(19) United States
(12) Patent Application Publication
(10) Pub. No.: US 2006/0237303 A1
(43) Pub. Date: Oct. 26, 2006

(54) Sputtering target, method of manufacturing a multilayer reflective film coated substrate, method of manufacturing a reflective mask blank, and method of manufacturing a reflective mask

(75) Inventors: Morio Hosoya, Tokyo (JP); Osamu Nozawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION

(21) Appl. No.: 11/392,769

(22) Filed: Mar. 30, 2006

(30) Foreign Application Priority Data
Mar. 31, 2005 (JP) 2005-100906
Mar. 31, 2005 (JP) 2005-100938

(51) Int. Cl. C23C 14/32; C23C 14/00

(52) U.S. Cl. 204/192.1; 204/298.12

(57) ABSTRACT

A sputtering target is substantially made of ruthenium (Ru), has a sintered density of 95% or more, and contains oxygen (O) and carbon (C) each in an amount of 200 ppm or less.

This application claims priority to prior Japanese patent applications JP 2005-100906 and 2005-100938, the disclosures of which are incorporated herein by reference.

### BACKGROUND OF THE INVENTION

This invention relates to a sputtering target for use in sputter deposition of a ruthenium film or a ruthenium compound film adapted to contribute to reflecting exposure light, a method of manufacturing a multilayer reflective film coated substrate including a film forming process by the use of such a sputtering target, and a method of manufacturing a reflective mask blank and a reflective mask by the use of such a substrate.

In recent years, following miniaturization of semiconductor devices, the extreme ultraviolet (EUV) lithography as the exposure technique using EUV light is promising in the semiconductor industry. It is noted here that the EUV light represents light in a wavelength band of the soft X-ray region or the vacuum ultraviolet ray region and, specifically, light having a wavelength of about 0.2 to 100 nm. As a mask for use in the EUV lithography, proposal has been made of an exposure reflective mask as described in Japanese Unexamined Patent Application Publication (JP-A) No. H08-213303.

Such a reflective mask comprises a multilayer reflective film for reflecting the EUV light on a substrate and an absorber film for absorbing the EUV light patterned on the multilayer reflective film. In an exposure apparatus (pattern transfer apparatus) with the reflective mask disposed therein, the exposure light incident on the reflective mask is absorbed at a portion where the absorber film pattern is present, while, is reflected by the multilayer reflective film at a portion where the absorber film pattern is not present. In this manner, a reflected optical image is transferred onto a semiconductor substrate (resist-coated silicon wafer) through a reflective optical system.

As the foregoing multilayer reflective film, use is normally made of a multilayer film in which a material having a relatively high refractive index and a material having a relatively low refractive index are alternately layered in the order of several nm. For example, a multilayer film having Si and Mo thin films alternately layered is known as a film having a high reflectance with respect to EUV light of 13 to 14 nm. On the multilayer reflective film, a protective film made of, for example, ruthenium (Ru) is formed for protecting the multilayer reflective film.

The multilayer reflective film can be formed on the substrate, for example, by sputtering. In the case of containing Si and Mo, a Si target and a Mo target are used to alternately carry out sputtering so as to layer Si and Mo films by 30 to 60 cycles, preferably by 40 cycles and, finally, a Si film is formed as an uppermost layer of the multilayer film. The ruthenium film serving as the protective film on the multilayer reflective film can also be formed by sputtering.

Japanese Unexamined Patent Application Publication (JP-A) No. 2001-295035 (Patent Document 1) discloses a sputtering target for use in forming electrodes or wiring used in a semiconductor device or the like. Herein, the sputtering target contains as a main component at least one kind of high melting point metal selected from W, Mo, Nb, Ta, and Ru. On the other hand, Japanese Unexamined Patent Application Publication (JP-A) No. 2002-327265 (Patent Document 2) discloses a high purity ruthenium target for use in forming a ruthenium thin film as a ferroelectric electrode or the like of a device Herein, the target has a forged structure containing oxygen and nitrogen each in an amount of 10 wtppm or less.

If particles are generated in such film formation, defects in a product (multilayer reflective film coated substrate, reflective mask blank, reflective mask) increase. Therefore, the high quality product cannot be obtained. In the case of pattern transfer using a conventional exposure transmission mask, the wavelength of exposure light is in the ultraviolet region (about 150 to 248 nm), i.e. relatively long. Consequently, even if concave and convex defects are generated on the surface of the mask, those defects cannot be serious. Therefore, conventionally, the generation of particles in the film formation was not particularly recognized as a problem in the field of exposure masks. However, when short-wavelength light such as EUV light is used as exposure light, a transfer image is largely affected even if fine concave and convex defects are formed on the surface of a mask. Therefore, the generation of particles cannot be ignored.

In the reflective mask using such EUV light as the exposure light, even if, for example, a convex defect of about several nm to several tens of nm is present on the surface of the multilayer reflective film, it could be a phase defect that affects a transfer image.

According to the study of the present inventor, it has been found that the generation of particles in film formation by normal sputtering is caused, for example, by abnormal discharge of a target. On the other hand, in a film forming process according to an ion beam deposition (IBD) method, since sputtering is carried out by the use of electrically neutral particles, no particles are generated due to abnormal discharge, while it has been found that the quality of a target is related to the generation of particles. Particularly, in the case where the ruthenium protective film is formed on the multilayer reflective film, if a defect is present on the surface of the ruthenium protective film, it could be a phase defect that affects a transfer image. Therefore, it is necessary to prevent as much as possible the generation of particles during deposition of the ruthenium protective film. Further, if particles generated during the film deposition are buried in the film, film stripping is often caused to occur due to those particles in a cleaning process after the film deposition. This not only further causes particles but also causes new concave and convex defects. Since the stress is large particularly in the case of ruthenium, film stripping tends to occur from the ruthenium protective film after the film deposition, and further, with respect also to ruthenium films once adhered to the inner side walls of a film forming apparatus, film stripping tends to occur due to stress relaxation. Both cases lead to increasing particles.

Accordingly, with respect to the reflective mask blank or the reflective mask that uses the short-wavelength light such as the EUV light as the exposure light, highly accurate particle control is required. However, since the generation of particles was not recognized as the problem conventionally, a measure has not been sufficiently discussed.

Patent Document 1 describes about reducing particles that are generated from the target upon sputter-depositing a high melting point metal film for forming electrodes or wiring used in a semiconductor device or the like. However, it describes nothing about the fact that there is the problem caused by the particles in the reflective mask blank or the reflective mask that uses the short-wavelength light such as the EUV light as the exposure light or that particles are generated other than those particles generated from the target during the film deposition. On the other hand, Patent Document 2 describes the sputtering target that is adapted to improve, through improvement in purity thereof, the electrical properties such as noise prevention at electrodes or the like. However, it describes nothing about the problem caused by the generation of particles in the reflective mask blank or the reflective mask that uses the short-wavelength light such as the EUV light as the exposure light or about a cause for generation of particles during the film deposition.

### SUMMARY OF THE INVENTION

It is therefore a first object of this invention to provide a sputtering target that can suppress particles to be generated from a target during film deposition and further suppress generation of particles due to film stripping from a film after the film deposition, film stripping from the inside of a film forming apparatus, or the like.

It is a second object of this invention to provide a manufacturing method that can suppress generation of particles due to abnormal discharge of a target, stripping of a ruthenium protective film or a ruthenium compound protective film after film deposition, film stripping from the inside of a film forming apparatus, thereby manufacturing a multilayer reflective film coated substrate with less surface defects.

It is a third object of this invention to provide a method of manufacturing a high quality exposure reflective mask blank with less surface defects.

It is a fourth object of this invention to provide a method of manufacturing a high quality exposure reflective mask with no pattern defect.

For solving the foregoing objects, this invention has the following structures.

(Structure 1)

A sputtering target for forming a ruthenium film adapted to contribute to reflecting exposure light, wherein:

the sputtering target is substantially made of ruthenium (Ru), has a sintered density of 95% or more, and contains oxygen (O) and carbon (C) each in an amount of 200 ppm or less.

According to Structure 1, the sputtering target is substantially made of ruthenium (Ru), has a sintered density of 95% or more, and contains oxygen (O) and carbon (C) each in an amount of 200 ppm or less. Therefore, it is possible to greatly reduce generation of particles during sputter deposition of the ruthenium film by the use of such a sputtering target.

The purity of the sputtering target is preferably controlled at the 3N (99.9 wt %) level or more. This is because it is possible to suppress reduction in reflectance with respect to EUV light due to the incorporation of impurities and generation of particles due to abnormal discharge during the sputter film deposition.

(Structure 2)

A sputtering target for forming a ruthenium compound film adapted to contribute to reflecting exposure light, wherein:

the sputtering target is made of a ruthenium compound containing ruthenium (Ru) and at least one selected from the group consisting of niobium (Nb), molybdenum (Mo), zirconium (Zr), titanium (Ti), lanthanum (La), silicon (Si), boron (B), and yttrium (Y), has a sintered density of 95% or more, and contains oxygen (O) in an amount of 2000 ppm or less and carbon (C) in an amount of 200 ppm or less.

According to Structure 2, the sputtering target is made of a ruthenium compound containing ruthenium (Ru) and at least one selected from the group consisting of niobium (Nb), molybdenum (Mo), zirconium (Zr), titanium (Ti), lanthanum (La), silicon (Si), boron (B), and yttrium (Y), has a sintered density of 95% or more, and contains oxygen (O) in an amount of 2000 ppm or less and carbon (C) in an amount of 200 ppm or less. Therefore, it is possible to greatly reduce generation of particles during sputter deposition of the ruthenium compound film by the use of such a sputtering target. Further, since the ruthenium compound can reduce the film stress as compared with ruthenium alone because of generation of stress relaxation due to lattice relaxation upon the film deposition, it is possible to suppress generation of particles due to film stripping from the ruthenium compound film formed by the use of such a target, film stripping from a ruthenium compound film adhered to the inside of a film forming apparatus, or the like.

The purity of the sputtering target is preferably controlled at the 3N (99.9 wt %) level or more. It is possible to suppress reduction in reflectance with respect to EUV light due to the incorporation of impurities and generation of particles due to abnormal discharge during the sputter film deposition caused by condensation of impurities at the crystal grain boundaries.

(Structure 3)

A sputtering target according to Structure 1 or 2, wherein:

the sputtering target has an average crystal grain size of 5 nm or more and 1000 nm or less.

According to Structure 3, the average crystal grain size of the sputtering target is controlled to 5 nm or more and 1000 nm or less. Therefore, it is possible to suitably suppress generation of particles during sputter deposition of the ruthenium compound film by the use of such a sputtering target.

(Structure 4)

A sputtering target according to Structure 1 or 2, wherein:

the sputtering target is used in a thin film forming process according to an ion beam deposition method.

During film deposition by normal sputtering, particles are generated, for example, due to abnormal discharge of a target. On the other hand, in the case of the ion beam deposition (IBD) method, since sputtering is carried out by the use of electrically neutral particles, no particles are generated due to abnormal discharge of a target. However, the quality of the target has an influence upon generation of particles. Since the sputtering target of this invention can suppress the generation of particles even if it is used in the film forming process according to the IBD method as recited in Structure 3, this invention is particularly suitable.

(Structure 5)

A method of manufacturing a multilayer reflective film coated substrate having on a substrate a multilayer reflective film for reflecting exposure light, wherein:

the method comprises a step of forming a ruthenium (Ru) protective film or a ruthenium (Ru) compound protective film on the multilayer reflective film by the use of the sputtering target according to Structure 1 or 2.

According to Structure 5, the multilayer reflective film coated substrate is manufactured by forming the ruthenium protective film or the ruthenium compound protective film on the multilayer reflective film by the use of the sputtering target according to Structure 1 or 2. Therefore, it is possible to suppress the generation of particles due to abnormal discharge of the target, stripping of the ruthenium film or the ruthenium compound film adhered to the inside of the film forming apparatus, stripping of the ruthenium protective film or the ruthenium compound protective film after the film deposition, or the like. As a result, the multilayer reflective film coated substrate with a very small amount of surface defects due to particles can be obtained.

(Structure 6)

A method of manufacturing a reflective mask blank, wherein:

the method comprises a step of forming an absorber film for absorbing the exposure light, on the ruthenium (Ru) protective film or the ruthenium (Ru) compound protective film of the multilayer reflective film coated substrate obtained by the method according to Structure 5.

According to Structure 6, the reflective mask blank is manufactured by using the multilayer reflective film coated substrate obtained by the manufacturing method according to Structure 5 and forming the absorber film for absorbing the exposure light, on the ruthenium protective film or the ruthenium compound protective film of the multilayer reflective film coated substrate. Therefore, it is possible to obtain the reflective mask blank with a very small amount of surface defects due to particles particularly on the surface of the ruthenium protective film or the ruthenium compound protective film that finally serves as a reflecting surface of a mask.

A buffer film having an etching stopper function for protecting the multilayer reflective film during pattern formation of the absorber film can be provided between the absorber film and the ruthenium protective film or the ruthenium compound protective film.

(Structure 7)

A method of manufacturing a reflective mask, wherein:

the method comprises a step of forming the absorber film of the reflective mask blank obtained by the method according to Structure 6, into an absorber film pattern that becomes a transfer pattern.

According to Structure 7, the reflective mask is manufactured by using the reflective mask blank according to Structure 6 and forming the absorber film of the reflective mask blank into the pattern. Therefore, it is possible to obtain the reflective mask with no pattern defect particularly caused by surface defects on the reflecting surface of the mask.

(Structure 8)

A method of manufacturing a semiconductor device, wherein:

the transfer pattern of the absorber film pattern formed on the reflective mask obtained by the method according to Structure 7 is transferred onto a semiconductor substrate.

According to Structure 8, the transfer pattern is transferred onto the semiconductor substrate by the use of the reflective mask obtained by the method according to Structure 7. Therefore, it is possible to obtain the semiconductor device free from defects.

According to this invention, it is possible to provide the sputtering target for forming the ruthenium film or the ruthenium compound film adapted to contribute to reflecting the exposure light, which can suppress particles to be generated from the target during the film deposition and further suppress the generation of particles due to film stripping from the film after the film deposition, film stripping from the inside of the film forming apparatus, or the like. Particularly, it is possible to provide the sputtering target that can suitably suppress the generation of particles even if it is used in the film forming process according to the IBD method.

Further, according to this invention, by forming the ruthenium protective film or the ruthenium compound protective film on the multilayer reflective film by the use of the sputtering target according to this invention, it is possible to suppress the generation of particles due to abnormal discharge of the target, film stripping from the ruthenium protective film or the ruthenium compound protective film after the film deposition, film stripping from the inside of the film forming apparatus, or the like. As a consequence, it is possible provide the multilayer reflective film coated substrate with a very small amount of surface defects due to particles.

Further, according to this invention, by using the foregoing multilayer reflective film coated substrate and forming the absorber film for absorbing the exposure light, on the ruthenium protective film or the ruthenium compound protective film, it is possible to provide the high quality reflective mask blank with a very small amount of surface defects due to particles particularly on the surface of the ruthenium protective film or the ruthenium compound protective film that serves as the reflecting surface of the mask.

Moreover, according to this invention, by using the foregoing reflective mask blank and forming the absorber film of the reflective mask blank into the absorber film pattern that becomes the transfer pattern, it is possible to provide the high quality reflective mask with no pattern defect particularly caused by surface defects on the reflecting surface of the mask.

### BRIEF DESCRIPTION OF THE DRAWINGS

FIG. 1 is a sectional view of a multilayer reflective film coated substrate obtained according to this invention;

FIGS. 2A to 2D are sectional views showing manufacturing processes of a reflective mask blank according to this invention and a reflective mask by the use of such a mask blank; and

FIG. 3 is a structural diagram showing a schematic structure of a pattern transfer apparatus used in Examples.

### DESCRIPTION OF THE PREFERRED EMBODIMENTS

Now, this invention will be described in detail in terms of preferred embodiments.

One embodiment of a sputtering target (hereinafter simply referred to as a “target”) according to this invention is a target substantially made of ruthenium (Ru), having a sintered density of 95% or more, and containing oxygen (O) and carbon (C) each in an amount of 200 ppm or less.

In this invention, by structuring the target as described above, it is possible to greatly reduce generation of particles upon sputter-depositing a ruthenium film by the use of such a target.

Herein, “substantially made of ruthenium (Ru)” represents that a main component of a material forming the target is ruthenium (Ru) and, even if other components are contained as impurities, the content thereof is 1000 ppm or less.

In the target of this invention, particularly oxygen (O) and carbon (C), among the impurities, are contained in small amounts each 200 ppm or less. Since the content of oxygen (O) and the content of carbon (C) are both low, it is possible to reduce particles generated from the target during the film deposition.

On the other hand, another embodiment of a sputtering target (hereinafter simply referred to as a “target”) according to this invention is a target made of a ruthenium compound containing ruthenium (Ru) and at least one selected from the group consisting of niobium (Nb), molybdenum (Mo), zirconium (Zr), titanium (Ti), lanthanum (La), silicon (Si), boron (B), and yttrium (Y), having a sintered density of 95% or more, and containing oxygen (O) in an amount of 2000 ppm or less and carbon (C) in an amount of 200 ppm or less.

In this invention, by structuring the target as described above, it is possible to greatly reduce generation of particles upon sputter-depositing a ruthenium compound film by the use of such a target. Further, since the film stress can be reduced in the ruthenium compound as compared with ruthenium alone, it is possible to suppress generation of particles due to film stripping from a ruthenium compound film formed by the use of such a target, film stripping from a ruthenium compound film adhered to the inside of a film forming apparatus, or the like.

Herein, with respect to the composition of the ruthenium compound containing ruthenium (Ru) and at least one selected from the group consisting of niobium (Nb), molybdenum (Mo), zirconium (Zr), titanium (Ti), lanthanum (La), silicon (Si), boron (B), and yttrium (Y), the content of niobium (Nb), molybdenum (Mo), zirconium (Zr), titanium (Ti), lanthanum (La), or silicon (Si) is preferably in the range of 3 to 75 at % and, particularly in terms of improving chemical resistance, in the range of 40 to 75 at %. On the other hand, since boron (B) and yttrium (Y) are each a metal that is susceptible to oxidation, if the content of such a metal is high, an oxide layer may be formed on the surface of a deposited ruthenium compound film so as to degrade the optical properties (e.g. reflectance of EUV light). Therefore, the content of it in the compound is preferably in the range of 3 to 50 at %.

In the target of this invention, particularly oxygen (O) and carbon (C), among the impurities, are contained in an amount of 2000 ppm or less and in an amount of 200 ppm or less, respectively. Since the content of oxygen (O) and the content of carbon (C) are both low, it is possible to reduce particles generated from the target during the film deposition.

Further, in the target of this invention, the sintered density is 95% or more. The target of this invention is obtained, for example, according to a method in which material powder of the ruthenium compound is once melted by an electron beam or the like and purified, then the high purity material powder is molded and sintered by various methods to thereby obtain a target. Since the sintered density of the obtained target is 95% or more, it is possible to reduce particles generated from the target during the film deposition. In this invention, it is more preferable that the sintered density be 99% or more. In this invention, the sintered density of the target is a value calculated from its volume, weight, and composition obtained by X-ray photoelectron spectroscopy (XPS).

In order to reduce particularly oxygen (O) and carbon (C) among the impurities contained in the target, it is preferable, for example, to perform hydrogen reduction or plasma treatment after producing the target or before producing the target, for example, upon producing a pellet so as to reduce the concentration of those impurities.

It is preferable that the target for deposition of the ruthenium film and the target for deposition of the ruthenium compound film of this invention each have an average crystal grain size of 5 nm or more and 1000 nm or less. By controlling the average crystal grain size in the target to 5 nm or more and 1000 nm or less, it is possible to suitably suppress generation of particles upon sputter-depositing the ruthenium film or the ruthenium compound film by the use of this target. In view of reducing the generation of particles, the crystal grain size is preferably as small as possible. However, if the average crystal grain size is less than 5 nm, the target manufacturing cost becomes high and, further, it is difficult to obtain the crystal grain size of less than 5 nm according to a powder sintering method. In this invention, it is more preferable that the average crystal grain size be in the range of 5 to 200 nm.

Moreover, it is preferable that the target for deposition of the ruthenium film and the target for deposition of the ruthenium compound film of this invention each have a purity of 3N or more. By controlling the purity of the target at the 3N (99.9 wt %) level or more, it is possible to suppress reduction in reflectance with respect to EUV light due to the incorporation of impurities and generation of particles due to abnormal discharge during sputter film deposition caused by condensation of impurities at the crystal grain boundaries. The purity of the target can be controlled in the process of melting and purifying the ruthenium material powder before molding and sintering of the target.

The target for deposition of the ruthenium film and the target for deposition of the ruthenium compound film of this invention are each used in a thin film forming process by normal sputtering, but is preferably used, particularly, in a thin film forming process according to the ion beam deposition (IBD) method.

Film deposition by normal sputtering is carried out in the following manner.

Specifically, inert gas ions are extracted from a sputter ion source and irradiated onto a target. Then, atoms forming the target are expelled out due to collision with the ions so that a target substance is generated. The target substance adheres to a substrate placed at a position facing the target to form a thin film layer. Therefore, in the film forming process by normal sputtering, particles are generated, for example, due to abnormal discharge of the target. However, by the use of the target of this invention, it is possible to reduce particles generated by such abnormal discharge of the target.

On the other hand, in the case of the ion beam deposition (IBD) method, since sputtering is carried out by the use of electrically neutral particles, no particles are generated due to abnormal discharge of a target. However, in the case of a material having a large stress such as Ru, the target material (Ru) adhered to chamber wall surfaces of a sputtering apparatus may be subjected to film stripping due to the film stress and scattered to adhere to the substrate, thereby forming particles. Particularly, it has been found that, in the case of the target for deposition of the ruthenium compound film, the quality of the target, in which Ru is alloyed to relax the stress, has an influence upon the generation of particles, while, the generation of particles cannot be reduced by the use of the conventional Ru target. Since the target of this invention can effectively suppress the generation of particles even if it is used in the film forming process according to the IBD method, this invention is particularly suitable.

Now, description will be made about a manufacturing method of a multilayer reflective film coated substrate according to this invention.

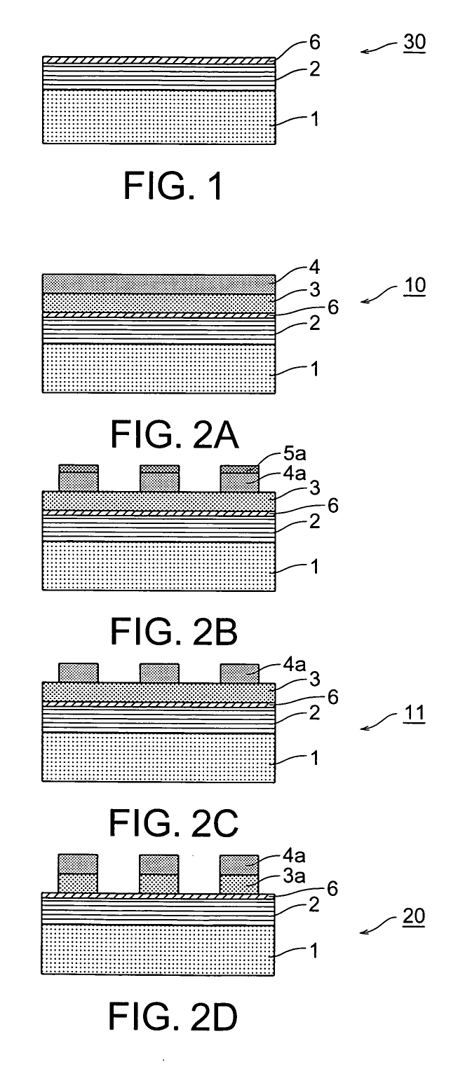

FIG. 1 is a sectional view of the multilayer reflective film coated substrate. According to FIG. 1, the multilayer reflective film coated substrate 30 comprises a substrate 1, a multilayer reflective film 2 formed on the substrate 1 and reflecting exposure light, and a protective film made of a ruthenium compound (hereinafter referred to as a “ruthenium compound protective film”) or a ruthenium protective film 6 formed on the multilayer reflective film 2. According to the multilayer reflective film coated substrate manufacturing method of this invention, the multilayer reflective film coated substrate 30 is obtained by depositing the ruthenium compound protective film or the ruthenium protective film 6 on the multilayer reflective film 2 by the use of the target of this invention.

Specifically, since the ruthenium compound protective film or the ruthenium protective film 6 is formed on the multilayer reflective film 2 by the use of the target of this invention, it is possible to suppress the generation of particles due to abnormal discharge of the target, stripping of the ruthenium compound film adhered to the inside of the film forming apparatus, stripping of the ruthenium compound protective film 6 after the film deposition, or the like. Thus, the multilayer reflective film coated substrate with a very small amount of surface defects due to particles can be obtained.

As the substrate 1, a glass substrate can be suitably used. The glass substrate is excellent in smoothness and flatness and thus is particularly suitable as a substrate for a mask. As a material of the glass substrate, use is made an amorphous glass (e.g. SiO₂—TiO₂-based glass) having a low thermal expansion coefficient, a quartz glass, a crystallized glass precipitated with β-quartz solid solution, or the like. The substrate preferably has a smooth surface of 0.2 nmRms or less and a flatness of 100 nm or less for achieving a high reflectance and transfer accuracy. In this invention, the unit Rms showing the smoothness represents the root mean square roughness and can be measured by an atomic force microscope. Further, the flatness in this invention is a value indicative of surface warp (deformation) given by TIR (total indicated reading). This is an absolute value of a difference between the highest position of the surface of the substrate located above a focal plane, given as a plane determined by the method of least squares on the basis of the surface of the substrate, and the lowest position located below the focal plane. The smoothness represents a smoothness in 10 μm square area and the flatness represents a flatness in 142 mm square area.

The multilayer reflective film 2 formed on the substrate 1 has a structure in which materials having different refractive indices are alternately layered and is capable of reflecting light having a specific wavelength. For example, use is made of a Mo/Si multilayer reflective film having a high reflectance with respect to EUV light of 13 to 14 nm, in which Mo and Si are alternately layered by approximately 40 cycles. As examples of other multilayer reflective films for use in the region of EUV light, use is made of a Ru/Si cycle multilayer reflective film, a Mo/Be cycle multilayer reflective film, a Mo compound/Si compound cycle multilayer reflective film, a Si/Nb cycle multilayer reflective film, a Si/Mo/Ru cycle multilayer reflective film, a Si/Mo/Ru/Mo cycle multilayer reflective film, a Si/Ru/Mo/Ru cycle multilayer reflective film, and so on. The multilayer reflective film 2 can be formed on the substrate 1, for example, by normal sputtering.

As described above, the ruthenium compound protective film or the ruthenium protective film 6 on the multilayer reflective film 2 is formed by normal sputtering or the IBD method by the use of the target of this invention. In this case, it is appropriate that the thickness of the ruthenium compound protective film or the ruthenium protective film 6 be properly selected in the range of 1.0 to 4.0 nm in view of reflectance. It is more preferable that the thickness be selected so as to make maximum the reflectance of light that is reflected on the protective film in a reflection area. However, it is necessary to consider a physical film thickness reduction, for example, due to etching of a buffer film or an absorber film on the protective film 6 in the manufacturing process of a reflective mask. Therefore, it is desirable to select the thickness that makes the reflectance maximum when such a film thickness reduction is caused.

The multilayer reflective film coated substrate having the multilayer reflective film and the ruthenium compound protective film or the ruthenium protective film formed on the substrate as described above is used, for example, as a multilayer reflective film coated substrate in an EUV reflective mask blank or an EUV reflective mask or a multilayer reflective film mirror in the EUV lithography system.

Now, description will be made about a manufacturing method of a reflective mask blank according to this invention.

By forming an absorber film for absorbing the exposure light, on the ruthenium compound protective film or the ruthenium protective film of the multilayer reflective film coated substrate according to this invention, the exposure reflective mask blank is obtained. According to necessity, a buffer film having resistance to etching environment during pattern formation of the absorber film for protecting the multilayer reflective film may be interposed between the ruthenium compound protective film or the ruthenium protective film and the absorber film. Since the reflective mask blank is manufactured by using the multilayer reflective film coated substrate according to this invention and forming the absorber film on its ruthenium compound protective film or ruthenium protective film, it is possible to obtain the reflective mask blank with a very small amount of surface defects due to particles on the surface of the ruthenium compound protective film or the ruthenium protective film that finally serves as a reflecting surface of a mask.

FIG. 2A is a sectional view of one embodiment of a reflective mask blank obtained by this invention. According to FIG. 2A, the reflective mask blank 10 has a buffer film 3 and an absorber film 4 in order on the ruthenium compound protective film 6 of the foregoing multilayer reflective film coated substrate.

As a material of the absorber film 4, a selection is made of a material having a high exposure light absorptance and a sufficiently large etching selectivity to the film (the buffer film in this embodiment, but, in a structure having no buffer film, the ruthenium compound protective film or the ruthenium protective film) located under the absorber film. For example, a material containing Ta as a main metal component is preferable. In this case, if a material containing Cr as a main component is used as the buffer film, it is possible to achieve a large etching selectivity (10 or more). The material containing Ta as the main metal element is normally a metal or an alloy. In view of smoothness and flatness, the material preferably has an amorphous or crystallite structure. As the material containing Ta as the main metal element, use can be made of a material containing Ta and B, a material containing Ta and N, a material containing Ta, B, and O, a material containing Ta, B, and N, a material containing Ta and Si, a material containing Ta, Si, and N, a material containing Ta and Ge, a material containing Ta, Ge, and N, or the like. By adding B, Si, Ge, or the like to Ta, the amorphous material can be easily obtained to improve the smoothness. On the other hand, by adding N or O to Ta, the resistance to oxidation is improved. Therefore, an effect of improving the aging stability can be obtained.

As other absorber film materials, use can be made of a material containing Cr as a main component (chromium, chromium nitride, or the like), a material containing tungsten as a main component (tungsten nitride or the like), a material containing titanium as a main component (titanium, titanium nitride, or the like), and so on.

The absorber films each can be formed by normal sputtering. The thickness of the absorber film is set to a value that can sufficiently absorb the exposure light, for example, the EUV light and is normally set to about 30 to 100 nm.

The buffer film 3 serves as an etching stop layer to protect the underlying multilayer reflective film while the absorber film 4 is formed into a transfer pattern. In this embodiment, the buffer film 3 is formed between the ruthenium compound protective film or the ruthenium protective film on the multilayer reflective film and the absorber film. The buffer film may be provided according to necessity.

As a material of the buffer film, a selection is made of a material having a large etching selectivity to the absorber film. The etching selectivity between the buffer film and the absorber film is 5 or more, preferably 10 or more, and more preferably 20 or more. Further, the material is preferably low in stress and excellent in smoothness and, particularly, has a smoothness of 0.3 nmRms or less. From this point of view, the material forming the buffer film preferably has a crystallite or amorphous structure.

Generally, Ta, an Ta alloy, or the like is often used as a material of the absorber film. When the Ta-based material is used as the material of the absorber film, it is preferable to use a material containing Cr as the buffer film. For example, use is made of Cr alone or a material containing Cr and at least one element selected from nitrogen, oxygen, and carbon. Specifically, it is chromium nitride (CrN) or the like.

On the other hand, when Cr alone or a material containing Cr as a main component is used as the absorber film, use can be made, as the buffer film, of a material containing Ta as a main component, for example, a material containing Ta and B, a material containing Ta, B, and N, or the like.

Upon forming a reflective mask, the buffer film may be removed to a pattern shape in conformity with the pattern of the absorber film in order to prevent a reduction in reflectance of the mask. On the other hand, if it is possible to use a material with a large exposure light transmittance as the buffer film and to sufficiently reduce the thickness thereof, the buffer film may be left so as to cover the ruthenium compound protective film or the ruthenium protective film without removing it in the pattern. The buffer film can be formed, for example, by deposition such as normal sputtering (DC sputtering or RF sputtering) or the IBD method. Upon performing correction of the absorber film pattern by the use of a focused ion beam (FIB), the thickness of the buffer film is preferably set to about 20 to 60 nm, but, when the FIB is not used, may be set to about 5 to 15 nm.

By forming the absorber film of the thus obtained reflective mask blank into the predetermined transfer pattern, the exposure reflective mask is obtained.

The pattern formation of the absorber film can be carried out by the use of the lithography technique.

Referring to FIGS. 2A to 2D, at first, there is prepared the reflective mask blank 10 (see FIG. 2A) obtained by forming the buffer film 3 and the absorber film 4 on the ruthenium compound protective film or the ruthenium protective film 6 of the multilayer reflective film coated substrate 30 (see FIG. 1) according to this invention. Then, a resist layer is formed on the absorber film 4 of the reflective mask blank 10 and is then subjected to pattern writing and development to thereby form a predetermined resist pattern 5a (see FIG. 2B). Then, using this resist pattern 5a as a mask, the absorber film 4 is formed into a pattern 4a according to a technique such as etching. For example, in the case of the absorber film containing Ta as a main component, it is possible to apply dry etching using a chlorine gas or trifluoromethane.

By removing the remaining resist pattern 5a, a mask 11 formed with the predetermined absorber film pattern 4a is obtained, as shown in FIG. 2C.

After forming the absorber film 4 into the pattern 4a, the buffer film 3 is removed in conformity with the absorber film pattern 4a. Thus, there is obtained a reflective mask 20 (see FIG. 2D) in which the ruthenium compound protective film or the ruthenium protective film 6 on the multilayer reflective film is exposed in an area where the absorber film pattern 4a is not present. Herein, in the case of the buffer film, for example, made of the Cr-based material, it is possible to apply dry etching using a mixed gas containing chlorine and oxygen. In this event, the ruthenium compound protective film or the ruthenium protective film 6 protects the multilayer reflective film 2 against the dry etching of the buffer film 3. When the required reflectance is ensured without removing the buffer film 3, the buffer film 3 may be left on the multilayer reflective film 2 having the protective film 6 thereon, without processing the buffer film 3 into the pattern following the absorber film pattern.

According to this invention, since the reflective mask is produced by the use of the foregoing reflective mask blank, it is possible to obtain the reflective mask with no pattern defect particularly caused by surface defects on the reflecting surface of the mask.

### EXAMPLES

Now, the embodiment of this invention will be described in further detail in terms of Examples 1 and 2. There were prepared Ru targets for use in Examples 1 and 2 and Comparative Examples 1 and 2. The sintered density, the average crystal grain size, the content of oxygen (O), and the content of carbon (C) of those Ru targets were set to different values from each other by properly adjusting the purity of material powder, the grinding condition (grinding time) of the material powder, the sintering temperature, the sintering pressure, and so on.

### Example 1

As a substrate, a low expansion SiO₂—TiO₂-based glass substrate having a 152 mm square shape with a thickness of 6.3 mm was prepared. This glass substrate had a smooth surface of 0.12 nmRms and a flatness of 100 nm or less by mechanical polishing.

Then, alternately layered films made of Mo and Si suitable as a reflective film for a region of 13 to 14 nm exposure wavelength were formed on the substrate as a multilayer reflective film. The film deposition was carried out by the use of an ion beam sputtering apparatus. At first, a Si film was deposited to a thickness of 4.2 nm by the use of a Si target, then a Mo film was deposited to a thickness of 2.8 nm by the use of a Mo target and, given that this formed one cycle, Si and Mo films were layered by 40 cycles and, finally, a Si film was deposited to a thickness of 4 nm. The total thickness was 284 nm.

The number of particles on the surface of the multilayer reflective film of the thus obtained multilayer reflective film coated substrate was measured to be 12 over the entire substrate. The particles each had a size of 150 nm or more and were measured by the use of a defect inspection apparatus (MAGICS M-1320 manufactured by Lasertec Corporation).

Then, a ruthenium protective film was formed on the multilayer reflective film of the multilayer reflective film coated substrate. The film deposition was carried out by the use of an ion beam sputtering apparatus and the Ru target used in the film deposition had a sintered density of 99.5% and an average crystal grain size of 103 nm.

The average crystal grain size of the target was measured by scanning electron microscope (SEM) observation. Further, the composition of the target was analyzed by X-ray photoelectron spectroscopy (XPS). As a result, ruthenium (Ru) was contained in an amount of 99.9 wt % or more, and oxygen (O) and carbon (C) were contained as impurities each in an amount of 200 ppm or less.

The thickness of the ruthenium protective film deposited by the use of the Ru target was 4 nm.

After the deposition of the ruthenium protective film, the number of particles on the surface of the ruthenium protective film of the multilayer reflective film coated substrate was measured by the use of the foregoing defect inspection apparatus and found to be increased by 112 over the entire substrate.

Then, a buffer film made of chromium nitride (CrN:N=10 at %) was formed on the ruthenium protective film of the multilayer reflective film coated substrate. The film deposition was carried out by the use of a DC magnetron sputtering apparatus. The thickness was set to 20 nm.

Then, a film containing Ta as a main component and further containing B and N was formed on the buffer film as an absorber film with respect to exposure light having a wavelength of 13 to 14 nm. The film deposition was carried out by the use of a DC magnetron sputtering apparatus and by using a target containing Ta and B and adding nitrogen in an amount of 10% to Ar. The thickness was set to 70 nm as a thickness that can sufficiently absorb the exposure light. The composition ratio of the deposited TaBN film was such that Ta was 0.8, B was 0.1, and N was 0.1.

In the manner as described above, a reflective mask blank of Example 1 was obtained.

Then, the absorber film of this reflective mask blank was formed into a pattern. Thus, a reflective mask having a 16 Gbit-DRAM pattern on a 0.07 μm design rule was produced.

At first, an EB resist was coated on the reflective mask blank and a predetermined resist pattern was formed by EB writing and development. Then, using this resist pattern as a mask, dry etching was applied to the TaBN film being the absorber film by the use of chlorine. In this manner, an absorber film pattern was formed.

Then, using the absorber film pattern as a mask, dry etching was applied to the CrN film being the buffer film by the use of a mixed gas of chlorine and oxygen (mixing ratio was 1:1 by volume ratio). Thus, the buffer film was removed to a pattern shape in conformity with the absorber film pattern.

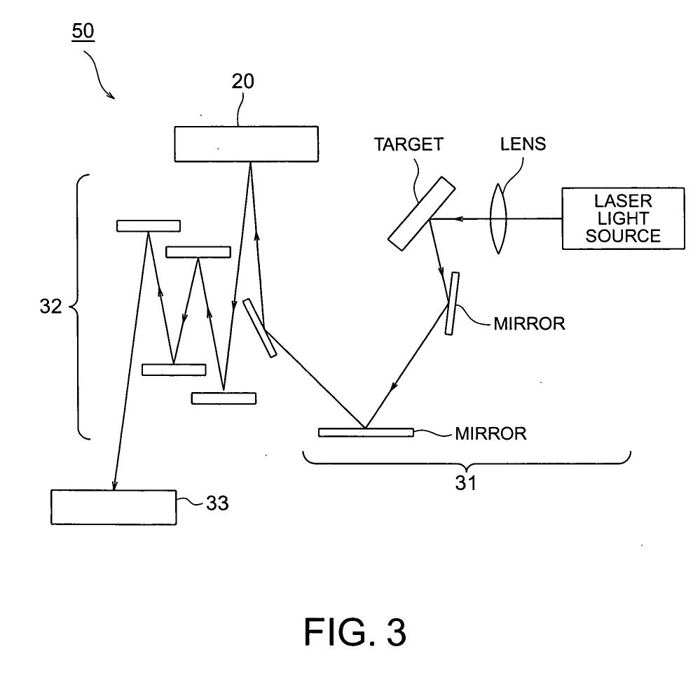

In the manner as described above, the reflective mask in Example 1 was obtained. The pattern defect was measured by the use of the foregoing defect inspection apparatus and it was found that there was no pattern defect due to particles. Further, using this reflective mask, pattern transfer onto a semiconductor substrate was carried out by the use of a pattern transfer apparatus 50 as shown in FIG. 3. The pattern transfer apparatus 50 is roughly formed by a laser plasma X-ray source 31, a reduction optical system 32, and so on. With this structure, a pattern reflected from a reflective mask 20 is normally reduced in size to about a quarter through the reduction optical system 32. Since the wavelength band of 13 to 14 nm was used as an exposure wavelength, it was set in advance that an optical path was located in a vacuum. In such a state, the EUV light obtained from the laser plasma X-ray source 31 was incident on the reflective mask 20 and light reflected therefrom was transferred onto a semiconductor substrate (resist-coated silicon wafer) 33 through the reduction optical system 32. As a result, an excellent transfer image was obtained on the semiconductor substrate.

### Example 2

Like in Example 1, a multilayer reflective film coated substrate having a multilayer reflective film of Si and Mo formed on a substrate was obtained. The number of particles on the surface of the multilayer reflective film of the obtained multilayer reflective film coated substrate was measured and it was 23 over the entire substrate.

Then, a ruthenium protective film was formed on the multilayer reflective film of the multilayer reflective film coated substrate. The film deposition was carried out by the use of an ion beam sputtering apparatus and the Ru target used in Example 2 had a sintered density of 99.8% and an average crystal grain size of 10 nm.

The composition of the target was analyzed by XPS. As a result, ruthenium (Ru) was contained in an amount of 99.9 wt % or more, and oxygen (O) and carbon (C) were contained as impurities each in an amount of 200 ppm or less.

The thickness of the ruthenium protective film deposited by the use of the Ru target was 4 nm.

After the deposition of the ruthenium protective film, the number of particles on the surface of the ruthenium protective film of the multilayer reflective film coated substrate was measured by the use of the foregoing defect inspection apparatus and found to be increased by 59 over the entire substrate.

Then, like in Example 1, a buffer film and an absorber film were formed on the ruthenium protective film of the multilayer reflective film coated substrate. Thus, a reflective mask blank was produced.

Then, like in Example 1, the absorber film of the reflective mask blank was formed into a pattern and, further, the buffer film was formed into a pattern following the pattern of the absorber film. In this manner, a reflective mask having a 16 Gbit-DRAM pattern on a 0.07 μm design rule was produced. The pattern defect was measured with respect to the obtained reflective mask and it was found that there was almost no pattern defect due to particles. Further, using this reflective mask, pattern transfer onto a semiconductor substrate was carried out and an excellent transfer image was obtained.

Now, Comparative Examples 1 and 2 to Examples 1 and 2 as described above will be given hereinbelow.

### Comparative Example 1

Like in Example 1, a multilayer reflective film coated substrate having a multilayer reflective film of Si and Mo formed on a substrate was obtained. The number of particles on the surface of the multilayer reflective film of the obtained multilayer reflective film coated substrate was measured and it was 22 over the entire substrate.

Then, a ruthenium protective film was formed on the multilayer reflective film of the multilayer reflective film coated substrate. The film deposition was carried out by the use of an ion beam sputtering apparatus like in Example 1 and the Ru target used in Comparative Example 1 had a sintered density of 92.3% and an average crystal grain size of 10 nm.

The composition of the target was analyzed by XPS. As a result, ruthenium (Ru) was contained in an amount of 99.9 wt % or more, and oxygen (O) and carbon (C) were contained as impurities wherein the content of oxygen exceeded 200 ppm.

The thickness of the ruthenium protective film deposited by the use of the Ru target was 4 nm.

After the deposition of the ruthenium protective film, the number of particles on the surface of the ruthenium protective film of the multilayer reflective film coated substrate was measured by the use of the foregoing defect inspection apparatus and found to be increased by 1513 over the entire substrate. It was found that when the ruthenium protective film was deposited by the use of the target of Comparative Example 1, a large number of particles were generated during the film deposition.

Then, like in Example 1, a buffer film and an absorber film were formed on the ruthenium protective film of the multilayer reflective film coated substrate. Thus, a reflective mask blank was produced.

Then, like in Example 1, the absorber film and the buffer film of the reflective mask blank were each formed into a pattern. In this manner, a reflective mask having a 16 Gbit-DRAM pattern on a 0.071 μm design rule was produced. The pattern defect was measured with respect to the obtained reflective mask and it was found that there were a large number of pattern defects due to particles.

### Comparative Example 2

Like in Example 1, a multilayer reflective film coated substrate having a multilayer reflective film of Si and Mo formed on a substrate was obtained. The number of particles on the surface of the multilayer reflective film of the obtained multilayer reflective film coated substrate was measured and it was 24 over the entire substrate.

Then, a ruthenium protective film was formed on the multilayer reflective film of the multilayer reflective film coated substrate. The film deposition was carried out by the use of an ion beam sputtering apparatus like in Example 2 and the Ru target used in Comparative Example 2 had a sintered density of 93.8% and an average crystal grain size of 10 nm.

The composition of the target was analyzed by XPS. As a result, ruthenium (Ru) was contained in an amount of 99.9 wt % or more, and oxygen (O) and carbon (C) were contained as impurities wherein the content of carbon exceeded 200 ppm.

The thickness of the ruthenium protective film deposited by the use of the Ru target was 4 nm.

After the deposition of the ruthenium protective film, the number of particles on the surface of the ruthenium protective film of the multilayer reflective film coated substrate was measured by the use of the foregoing defect inspection apparatus and found to be increased by 1158 over the entire substrate. It was found that when the ruthenium protective film was deposited by the use of the target of Comparative Example 2, a large number of particles were generated during the film deposition.

Then, like in Example 1, a buffer film and an absorber film were formed on the ruthenium protective film of the multilayer reflective film coated substrate. Thus, a reflective mask blank was produced.

Then, like in Example 1, the absorber film and the buffer film of the reflective mask blank were each formed into a pattern. In this manner, a reflective mask having a 16 Gbit-DRAM pattern on a 0.07 μm design rule was produced. The pattern defect was measured with respect to the obtained reflective mask and it was found that there were a large number of pattern defects due to particles.

Although not given in the foregoing Examples, the ruthenium protective film to be formed on the multilayer reflective film may be deposited by DC sputtering or RF sputtering other than the ion beam sputtering and the target of this invention can also be used as a target for the DC or RF sputtering.

Further, although not given in the foregoing Examples, the target of this invention is not limited to the deposition of the ruthenium protective film formed on the multilayer reflective film, but can also be used as a target for deposition of a Ru layer in a multilayer reflective film such as a Ru/Si cycle multilayer reflective film or a Si/Mo/Ru cycle multilayer reflective film.

Now, the other embodiment of this invention will be described in further detail in terms of Examples 3 to 8. There were prepared ruthenium compound targets for use in Examples 3 to 8 and Comparative Examples 3 and 4. The sintered density, the average crystal grain size, the content of oxygen (O), the content of carbon (C), and the content of each of metals such as niobium (Nb), zirconium (Zr), and molybdenum (Mo) of those ruthenium compound targets were set to different values from each other by properly adjusting the material and purity of material powder, the grinding condition (grinding time) of the material powder, the sintering temperature, the sintering pressure, and so on.

### Example 3

As a substrate, a low expansion SiO₂—TiO₂-based glass substrate having a 152 mm square shape with a thickness of 6.3 mm was prepared. This glass substrate had a smooth surface of 0.12 nmRms and a flatness of 100 nm or less by mechanical polishing.

Then, alternately layered films made of Mo and Si suitable as a reflective film for a region of 13 to 14 nm exposure wavelength were formed on the substrate as a multilayer reflective film. The film deposition was carried out by the use of an ion beam sputtering apparatus. At first, a Si film was deposited to a thickness of 4.2 nm by the use of a Si target, then a Mo film was deposited to a thickness of 2.8 nm by the use of a Mo target and, given that this formed one cycle, Si and Mo films were layered by 40 cycles and, finally, a Si film was deposited to a thickness of 4 nm. The total thickness was 284 nm.

The number of particles on the surface of the multilayer reflective film of the thus obtained multilayer reflective film coated substrate was measured to be 12 over the entire substrate. The particles each had a size of 150 nm or more and were measured by the use of a defect inspection apparatus (MAGICS M-1320 manufactured by Lasertec Corporation).

Then, a RuNb protective film was formed on the multilayer reflective film of the multilayer reflective film coated substrate. The film deposition was carried out by the use of an ion beam sputtering apparatus and the RuNb target used in the film deposition had a sintered density of 99.5% and an average crystal grain size of 76 nm. The average crystal grain size of the target was measured by scanning electron microscope (SEM) observation.

Further, the composition of the target was analyzed by X-ray photoelectron spectroscopy (XPS). As a result, ruthenium (Ru) was contained in an amount of 79 at % and niobium (Nb) in an amount of 21 at %, and oxygen (O) and carbon (C) were contained as impurities in an amount of 2000 ppm or less and in an amount of 200 ppm or less, respectively.

The thickness of the RuNb protective film deposited by the use of the RuNb target was 4 nm.

After the deposition of the RuNb protective film, the number of particles on the surface of the RuNb protective film of the multilayer reflective film coated substrate was measured by the use of the foregoing defect inspection apparatus. As a result, the increased number was very small, i.e. only two over the entire substrate.

Then, a buffer film made of chromium nitride (CrN: N=10 at %) was formed on the RuNb protective film of the multilayer reflective film coated substrate. The film deposition was carried out by the use of a DC magnetron sputtering apparatus. The thickness was set to 20 nm.

Then, a film containing Ta as a main component and further containing B and N was formed on the buffer film as an absorber film with respect to exposure light having a wavelength of 13 to 14 nm. The film deposition was carried out by the use of a DC magnetron sputtering apparatus and by using a target containing Ta and B and adding nitrogen in an amount of 10% to Ar. The thickness was set to 70 nm as a thickness that can sufficiently absorb the exposure light. The composition ratio of the deposited TaBN film was such that Ta was 0.8, B was 0.1, and N was 0.1.

In the manner as described above, a reflective mask blank of Example 3 was obtained.

Then, the absorber film of this reflective mask blank was formed into a pattern. Thus, a reflective mask having a 16 Gbit-DRAM pattern on a 0.07 μm design rule was produced.

At first, an EB resist was coated on the reflective mask blank and a predetermined resist pattern was formed by EB writing and development. Then, using this resist pattern as a mask, dry etching was applied to the TaBN film being the absorber film by the use of chlorine. In this manner, an absorber film pattern was produced.

Then, using the absorber film pattern as a mask, dry etching was applied to the CrN film being the buffer film by the use of a mixed gas of chlorine and oxygen (mixing ratio was 1:1 by volume ratio). Thus, the buffer film was removed to a pattern shape in conformity with the absorber film pattern.

In the manner as described above, the reflective mask in Example 3 was obtained. The pattern defect was measured by the use of the foregoing defect inspection apparatus and it was found that there was no pattern defect due to particles. Further, using this reflective mask, pattern transfer onto a semiconductor substrate was carried out by the use of a pattern transfer apparatus 50 as shown in FIG. 3. The pattern transfer apparatus 50 is roughly formed by a laser plasma X-ray source 31, a reduction optical system 32, and so on. With this structure, a pattern reflected from a reflective mask 20 is normally reduced in size to about a quarter through the reduction optical system 32. Since the wavelength band of 13 to 14 nm was used as an exposure wavelength, it was set in advance that an optical path was located in a vacuum. In this state, the EUV light obtained from the laser plasma X-ray source 31 was incident on the reflective mask 20 and light reflected therefrom was transferred onto a semiconductor substrate (resist-coated silicon wafer) 33 through the reduction optical system 32. As a result, an excellent transfer image was obtained on the semiconductor substrate.

### Example 4

A RuNb protective film was formed on a multilayer reflective film of a multilayer reflective film coated substrate obtained like in Example 3. In Example 4, the film deposition was carried out by the use of a DC magnetron sputtering apparatus and the RuNb target used in the film deposition was the same as that used in Example 3 except that the sintered density was 99.3%.

After the deposition of the RuNb protective film, the number of particles on the surface of the RuNb protective film of the multilayer reflective film coated substrate was measured by the use of the foregoing defect inspection apparatus and found to be increased by 8 over the entire substrate as compared with that before the protective film deposition.

Then, like in Example 3, a buffer film and an absorber film were formed on the RuNb protective film of the multilayer reflective film coated substrate. Thus, a reflective mask blank was produced.

Then, like in Example 3, the absorber film of the reflective mask blank was formed into a pattern and, further, the buffer film was formed into a pattern following the pattern of the absorber film. In this manner, a reflective mask having a 16 Gbit-DRAM pattern on a 0.071 μm design rule was produced. The pattern defect was measured with respect to the obtained reflective mask and it was found that there was almost no pattern defect due to particles. Further, using this reflective mask, pattern transfer onto a semiconductor substrate was carried out and an excellent transfer image was obtained.

### Example 5

A RuZr protective film was formed on a multilayer reflective film of a multilayer reflective film coated substrate obtained like in Example 3. In Example 5, the film deposition was carried out by the use of an ion beam sputtering apparatus and the RuZr target used in the film deposition had a sintered density of 99.2% and an average crystal grain size of 81 nm. The composition of the target was analyzed by X-ray photoelectron spectroscopy (XPS). As a result, Ru was contained in an amount of 89 at % and Zr in an amount of 11 at %, and oxygen (O) and carbon (C) were contained as impurities in an amount of 2000 ppm or less and in an amount of 200 ppm or less, respectively.

The thickness of the RuZr protective film deposited by the use of the RuZr target was 4 nm.

After the deposition of the RuZr protective film, the number of particles on the surface of the RuZr protective film of the multilayer reflective film coated substrate was measured by the use of the foregoing defect inspection apparatus and found to be increased by 7 over the entire substrate as compared with that before the protective film deposition.

Then, like in Example 3, a buffer film and an absorber film were formed on the RuZr protective film of the multilayer reflective film coated substrate. Thus, a reflective mask blank was produced.

Then, by the use of the reflective mask blank, a reflective mask was produced like in Example 3. The pattern defect was measured with respect to the obtained reflective mask and it was found that there was almost no pattern defect due to particles. Further, using this reflective mask, pattern transfer onto a semiconductor substrate was carried out so that an excellent transfer image was obtained.

### Example 6

A RuZr protective film like in Example 5 was formed on a multilayer reflective film of a multilayer reflective film coated substrate obtained like in Example 3. In Example 6, the film deposition was carried out by the use of a DC magnetron sputtering apparatus and the RuZr target used in the film deposition was the same as that used in Example 5 except that the sintered density was 99.5%.

After the deposition of the RuZr protective film, the number of particles on the surface of the RuZr protective film of the multilayer reflective film coated substrate was measured by the use of the foregoing defect inspection apparatus and found to be increased by 12 over the entire substrate as compared with that before the protective film deposition.

Then, like in Example 3, a buffer film and an absorber film were formed on the RuZr protective film of the multilayer reflective film coated substrate. In this manner, a reflective mask blank was produced.

Then, by the use of the reflective mask blank, a reflective mask was produced like in Example 3. The pattern defect was measured with respect to the obtained reflective mask and it was found that there was almost no pattern defect due to particles. Further, using this reflective mask, pattern transfer onto a semiconductor substrate was carried out so that an excellent transfer image was obtained.

### Example 7

A RuMo protective film was formed on a multilayer reflective film of a multilayer reflective film coated substrate obtained like in Example 3. In Example 7, the film deposition was carried out by the use of an ion beam sputtering apparatus and the RuMo target used in the film deposition had a sintered density of 99.1% and an average crystal grain size of 58 nm. The composition of the target was analyzed by X-ray photoelectron spectroscopy (XPS). As a result, Ru was contained in an amount of 92 at % and Mo in an amount of 8 at %, and oxygen (O) and carbon (C) were contained as impurities in an amount of 2000 ppm or less and in an amount of 200 ppm or less, respectively.

The thickness of the RuMo protective film deposited by the use of the RuMo target was 4 nm.

After the deposition of the RuMo protective film, the number of particles on the surface of the RuMo protective film of the multilayer reflective film coated substrate was measured by the use of the foregoing defect inspection apparatus and found to be increased by 8 over the entire substrate as compared with that before the protective film deposition.

Then, like in Example 3, a buffer film and an absorber film were formed on the RuMo protective film of the multilayer reflective film coated substrate. Thus, a reflective mask blank was produced.

Then, by the use of the reflective mask blank, a reflective mask was produced like in Example 3. The pattern defect was measured with respect to the obtained reflective mask and it was found that there was almost no pattern defect due to particles. Further, using this reflective mask, pattern transfer onto a semiconductor substrate was carried out so that an excellent transfer image was obtained.

### Example 8

A RuMo protective film like in Example 7 was formed on a multilayer reflective film of a multilayer reflective film coated substrate obtained like in Example 3. In Example 8, the film deposition was carried out by the use of a DC magnetron sputtering apparatus and the RuMo target used in the film deposition was the same as that used in Example 7 except that the sintered density was 99.5%.

After the deposition of the RuMo protective film, the number of particles on the surface of the RuMo protective film of the multilayer reflective film coated substrate was measured by the use of the foregoing defect inspection apparatus and found to be increased by 9 over the entire substrate as compared with that before the protective film deposition.

Then, like in Example 3, a buffer film and an absorber film were formed on the RuMo protective film of the multilayer reflective film coated substrate. In this manner, a reflective mask blank was produced.

Then, by the use of the reflective mask blank, a reflective mask was produced like in Example 3. The pattern defect was measured with respect to the obtained reflective mask and it was found that there was almost no pattern defect due to particles. Further, using this reflective mask, pattern transfer onto a semiconductor substrate was carried out so that an excellent transfer image was obtained.

Now, Comparative Examples 3 and 4 to Examples 3 to 8 as described above will be given hereinbelow.

### Comparative Example 3

A ruthenium protective film was formed on a multilayer reflective film of a multilayer reflective film coated substrate obtained like in Example 3. The film deposition was carried out by the use of an ion beam sputtering apparatus like in Example 3 and the Ru target used in Comparative Example 3 had a sintered density of 92.3% and an average crystal grain size of 10 nm. The composition of the target was analyzed by XPS. As a result, ruthenium (Ru) was contained in an amount of 99.9 wt % or more, and oxygen (O) and carbon (C) were contained as impurities. In particular, the content of oxygen exceeded 200 ppm.

The thickness of the ruthenium protective film deposited by the use of the Ru target was 4 nm.

After the deposition of the ruthenium protective film, the number of particles on the surface of the ruthenium protective film of the multilayer reflective film coated substrate was measured by the use of the foregoing defect inspection apparatus and found to be increased by 1513 over the entire substrate as compared with that before the protective film deposition. It was found that when the ruthenium protective film was deposited by the use of the target of Comparative Example 3, a large number of particles were generated during the film deposition. This is considered to be caused by abnormal discharge of the target and, further, by stripping of a ruthenium film adhered to the inside (chamber inner wall) of the sputtering apparatus, stripping of the deposited ruthenium protective film, and so on.

Then, like in Example 3, a buffer film and an absorber film were formed on the ruthenium protective film of the multilayer reflective film coated substrate. Thus, a reflective mask blank was produced. Then, by the use of the reflective mask blank, a reflective mask was produced like in Example 3. The pattern defect was measured with respect to the obtained reflective mask and it was found that there were a large number of pattern defects due to particles.

### Comparative Example 4

A RuMo protective film was formed on a multilayer reflective film of a multilayer reflective film coated substrate obtained like in Example 3. In Example 4, the film deposition was carried out by the use of an ion beam sputtering apparatus and the RuMo target used in the film deposition had a sintered density of 92.3% and an average crystal grain size of 112 nm. The composition ratio of the target was such that Ru was contained in an amount of 92 at % and Mo in an amount of 8 at %, and oxygen (O) and carbon (C) were contained as impurities in an amount exceeding 2000 ppm and in an amount exceeding 200 ppm, respectively.

After the deposition of the RuMo protective film, the number of particles on the surface of the RuMo protective film of the multilayer reflective film coated substrate was measured by the use of the foregoing defect inspection apparatus and found to be increased by 63 over the entire substrate as compared with that before the protective film deposition. It was found that when the RuMo protective film was deposited by the use of the target of Comparative Example 4, a large number of particles were generated during the film deposition.

Then, like in Example 3, a buffer film and an absorber film were formed on the RuMo protective film of the multilayer reflective film coated substrate. Thus, a reflective mask blank was produced. Then, by the use of the reflective mask blank, a reflective mask was fabricated like in Example 3. The pattern defect was measured with respect to the obtained reflective mask and it was found that there were a large number of pattern defects due to particles.

What is claimed is:

1. A sputtering target for forming a ruthenium film adapted to contribute to reflecting exposure light, wherein:
the sputtering target is substantially made of ruthenium (Ru), has a sintered density of 95% or more, and contains oxygen (O) and carbon (C) each in an amount of 200 ppm or less.

2. A sputtering target for forming a ruthenium compound film adapted to contribute to reflecting exposure light, wherein:
the sputtering target is made of a ruthenium compound containing ruthenium (Ru) and at least one selected from the group consisting of niobium (Nb), molybdenum (Mo), zirconium (Zr), titanium (Ti), lanthanum (La), silicon (Si), boron (B), and yttrium (Y), has a sintered density of 95% or more, and contains oxygen (O) in an amount of 2000 ppm or less and carbon (C) in an amount of 200 ppm or less.

3. A sputtering target according to claim 1 or 2, wherein:
the sputtering target has an average crystal grain size of 5 nm or more and 1000 nm or less.

4. A sputtering target according to claim 1 or 2, wherein:
the sputtering target is used in a thin film forming process according to an ion beam deposition method.

5. A method of manufacturing a multilayer reflective film coated substrate having on a substrate a multilayer reflective film for reflecting exposure light, wherein:
the method comprises a step of forming a ruthenium (Ru) protective film or a ruthenium (Ru) compound protective film on the multilayer reflective film by the use of the sputtering target according to claim 1 or 2.

6. A method of manufacturing a reflective mask blank, wherein:
the method comprises a step of forming an absorber film for absorbing the exposure light, on the ruthenium (Ru) protective film or the ruthenium (Ru) compound protective film of the multilayer reflective film coated substrate obtained by the method according to claim 5.

7. A method of manufacturing a reflective mask, wherein:
the method comprises a step of forming the absorber film of the reflective mask blank obtained by the method according to claim 6, into an absorber film pattern that becomes a transfer pattern.

8. A method of manufacturing a semiconductor device, wherein:
the transfer pattern of the absorber film pattern formed on the reflective mask obtained by the method according to claim 7 is transferred onto a semiconductor substrate.
